(19) United States
(12) Patent Application Publication
(10) Pub. No.: US 2025/0385454 A1
(43) Pub. Date: Dec. 18, 2025

(54) APPARATUS AND METHOD OF MAKING AND USING MULTI-CONDUCTOR CABLES ON FLEXIBLE SILICON CABLES WITH RESISTIVE AND SUPERCONDUCTING APPLICATIONS

(71) Applicant: Government of the United States of America, as represented by the Secretary of Commerce, Gaithersburg, MD (US)

(72) Inventors: Galen O'Neil, Boulder, CO (US); Daniel Richard Schmidt, Boulder, CO (US); Nathan Joel Ortiz, Arvada, CO (US); Joel Nathan Ullom, Boulder, CO (US); Joel Calvin Weber, Erie, CO (US); Robinjeet Singh, Superior, CO (US)

(21) Appl. No.: 19/239,343

(22) Filed: Jun. 16, 2025

Related U.S. Application Data
(60) Provisional application No. 63/660,204, filed on Jun. 14, 2024.

(51) Int. Cl. H01R 12/79; H01R 43/16

(52) U.S. Cl. CPC H01R 12/79; H01R 43/16

(57) ABSTRACT

A method to create flexible mutli-conductor cables include fabricating wiring on silicon-on-insulator wafers with lithographic fabrication techniques followed by thinning some sections of the wafer with a silicon etch. Exemplary cables can have fine pitch and low thermal conductivity enabling high density superconducting interconnects between different temperature stages in cryogenic platforms or between superconducting circuits oriented perpendicular to each other. Also presented herein are methods for making and using exemplary cables.

### FEDERALLY-SPONSORED RESEARCH AND DEVELOPMENT

This invention was made with United States Government support from the National Institute of Standards and Technology (NIST), an agency of the United States Department of Commerce. The Government has certain rights in this invention.

### COPYRIGHT NOTICE

This patent disclosure may contain material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### FIELD OF INVENTION

The present invention relates generally to miniature cables, and more particularly to miniature flexible silicon cables.

### BACKGROUND

Flexible circuits are often used as connectors in application where flexibility or space savings are critical at room temperature. The same properties are desirable for low temperature detector (LTD) applications, except that LTD applications typically require superconducting or at least very low resistance wiring.

### SUMMARY OF INVENTION

Many flexible wirings solutions exist commercially, but most do not support superconducting materials necessary for LTDs or provide a required level of integration. Here we present silicon on insulator (SOI) flex which provides a flexible circuitry solution that easily integrates into existing LTD detector and readout fabrication processes, works with many superconducting materials, supports high wiring density, and can serve as a weak thermal link when desired.

Therefore, presented herein are methods to create flexible mutli-conductor cables by fabricating wiring on silicon-on-insulator wafers with lithographic fabrication techniques followed by thinning some portions of the wafer with a silicon etch. Exemplary cables can have fine pitch and low thermal conductivity enabling high density superconducting interconnects between different temperature stages in cryogenic platforms or between superconducting circuits oriented perpendicular to each other. Also presented herein are methods for making and using exemplary cables.

According to an aspect of the invention, a method of fabricating a flexible circuitry device using semiconductor processing includes the steps of: fabricating wiring and/or circuitry on a device layer of a silicon-on-insulator wafer having a thick, relative to other layers of the flexible circuitry device, silicon handle layer, a buried oxide layer, and the device layer; etching a pattern in the device and buried oxide layers; and removing a portion of the handle layer from the wafer using a backside deep silicone etch, thereby leaving an area having only the device layer plus the added wiring and/or circuitry and is thereby flexible at that relatively thin silicon layer.

Optionally, the silicon device layer is 1-20 microns thick.

Optionally, the silicon device layer is under 4 microns thick.

Optionally, the device layer is a semiconductor grade monocrystalline Silicon layer.

Optionally, the backside deep silicone etch is a backside silicon deep reactive ion etch.

Optionally, the method includes the step of removing the buried oxide layer.

According to another aspect of the invention, a flexible circuitry device manufactured by semiconductor processing includes first rigid semiconductor portion having a silicon device layer and a handle layer, the handle layer of the first portion being thick relative to the device layer of the first portion; a second rigid semiconductor portion having a silicon device layer and a handle layer, the handle layer of the second portion being thick relative to the device layer of the second portion; and a flexible portion connecting the first rigid portion and the second rigid portion, the flexible portion having wiring electrically connecting a portion of the first rigid portion to the second rigid portion.

Optionally, the wiring is resistive wiring.

Optionally, the wiring is superconducting wiring.

Optionally, the first rigid portion includes circuit elements fabricated on the device layer of the first rigid portion.

Optionally, the flexible portion is monolithic with the device layers of the first and second rigid portions.

According to another aspect of the invention, a method of using a flexible circuitry device having a flexible portion includes the steps of: mounting the flexible circuitry device on a sample box of a jigging assembly using alignment features of the sample box tending to accept and cradle the flexible circuitry device when being mounted on the sample box; bending the flexible circuitry device at the flexible portion using a bender of the jigging assembly, the bender guided by a guide of the jigging assembly; and removing the flexible circuitry device from the jigging.

Optionally, the guide includes slots configured to accept rails of the bender.

Optionally, the flexible circuitry device is bent approximately 90 degrees.

Optionally, during bending, the flexible portion is protected by the jigging assembly and not touched by any portions of the jigging assembly.

Optionally, the method includes the step of the bender remaining in place while mechanical fasteners are inserted through holes in the bender.

Optionally, during insertion of the mechanical fasteners the flexible portion is protected from accidental contact by a mechanical cover.

Optionally, the method includes the step of the bender remaining in place while mechanical fasteners are inserted through holes in the bender.

Optionally, the method includes the steps of removing the bender from the flexible circuitry device; and affixing a cover to the flexible circuitry device covering the flexible portion.

Optionally, the method includes the step of installing a final cover on the flexible circuitry device after removal from the jigging.

The foregoing and other features of the invention are hereinafter described in greater detail with reference to the accompanying drawings.

### BRIEF DESCRIPTION OF THE DRAWINGS

FIG. 1 shows an exemplary device with flexible wiring.

FIG. 2 shows a block diagram of an exemplary method of manufacturing an exemplary device with flexible wiring.

FIG. 3 shows the exemplary method of FIG. 2 in pictorial form with zoomed-in detail-insets for the third and fourth steps.

FIG. 4 shows a finished cross-section of exemplary device layers.

FIG. 5 shows a step of an exemplary process for using an exemplary device with flexible wiring.

FIG. 6 shows a step of an exemplary process for using an exemplary device with flexible wiring.

FIG. 7 shows a step of an exemplary process for using an exemplary device with flexible wiring.

FIG. 8 shows a step of an exemplary process for using an exemplary device with flexible wiring.

FIG. 9 shows a step of an exemplary process for using an exemplary device with flexible wiring.

FIG. 10 shows a step of an exemplary process for using an exemplary device with flexible wiring.

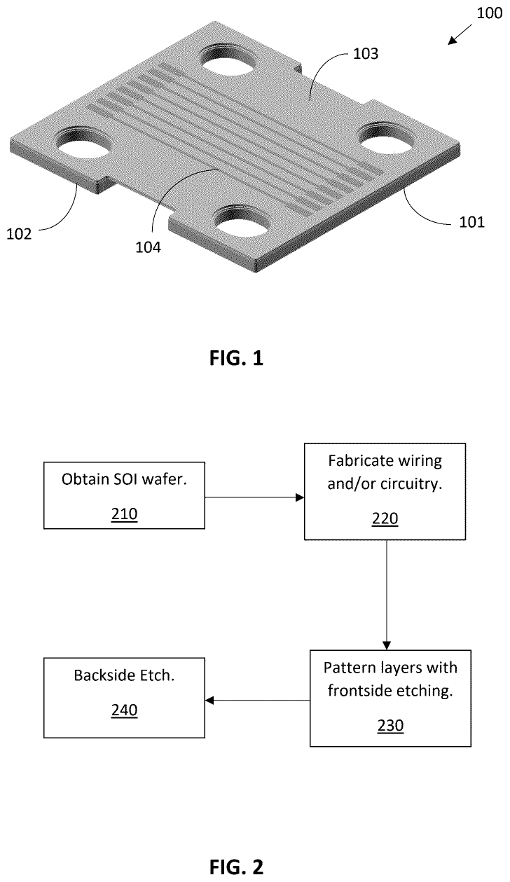

### DETAILED DESCRIPTION

Some LTD applications such as soft X-ray spectrometers based on large arrays of transition edge sensors (TES) benefit from an out-of-plane design. In these out-of-plane designs the readout circuitry, which is often larger than the sensors themselves, is located on a surface perpendicular to the plane of the sensors. Out-of-plane designs require less area in-plane, which allows the surrounding magnetic shields, radiation shields, and vacuum components to be more compact than with an in-plane design. Flexible superconducting circuitry is used to connect the in-plane sensors to the out-of-plane readout circuits. So far wirebonds have been used to connect from the sensors to the flexible circuits and from the flexible circuits to the sensors. Or the wirebonds have been used as the flexible circuits themselves. In these cases, the wiring density is therefore limited by the density of wirebonds for which 200 μm pair pitch is routine and 50 μm is plausible with bond-over-bond methods. In comparison, a 10 μm pair pitch with microstrip wiring running over exemplary SOI flex should be easily achievable.

An exemplary device 100 includes two silicon pieces 101, 102 linked by a flexible portion 103. The flexible portion 103 may have high density wiring 104 that is either resistive or superconducting, as well as arbitrary circuit elements 104 fabricated on it. Both silicon substrates may have arbitrary circuit elements fabricated on them as well.

An important use case of exemplary embodiments is for flexible wiring in an x-ray spectrometer using superconducting devices to enable the readout circuits to be out of plane from the detector elements to use space more efficiently than conventional spectrometers.

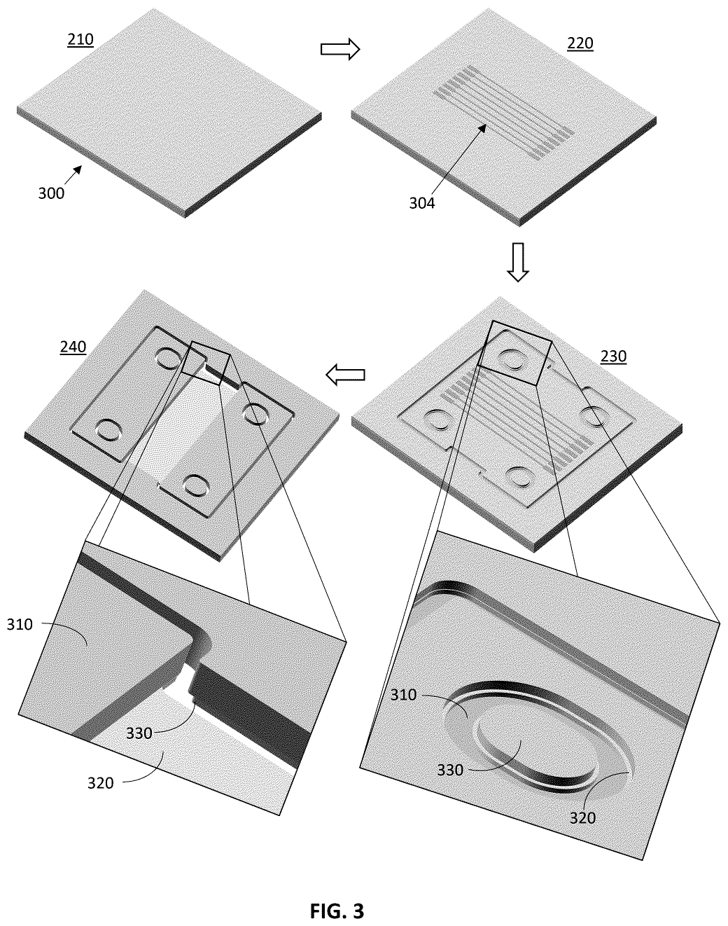

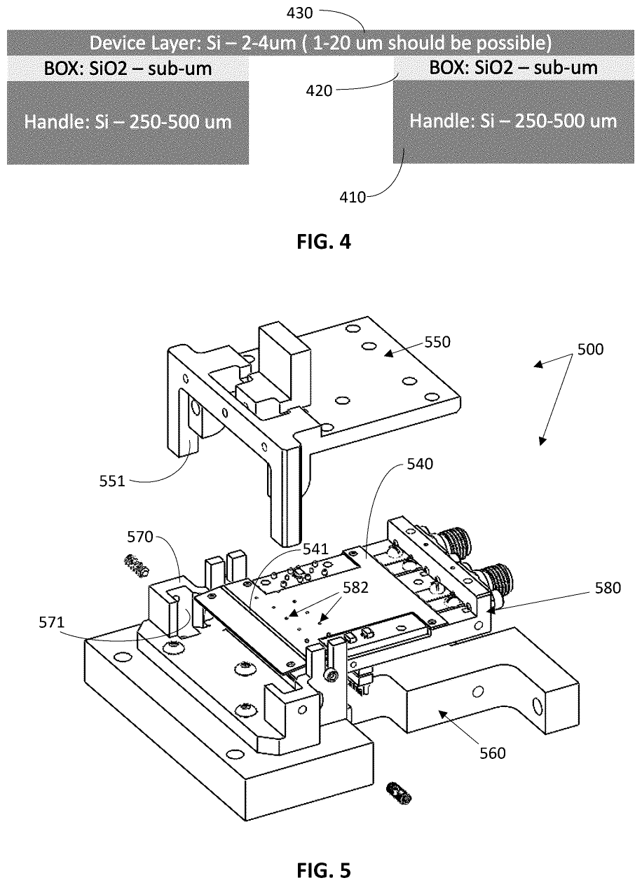

Referring now to FIG. 2-4, substantially the same structures are shown in FIGS. 3 and 4, and consequently the same reference numerals but indexed by 100 are used to denote structures corresponding to each other. A method 200 of fabricating a flexible circuitry device 100 begins at block 210 with a Silicon-on-Insulator (SOI) wafer 300, 400 having a thick (relative to the other device layers) Silicon handle (HAN) layer 310, 410 a buried oxide (BOX) layer 320,420 and a thin Silicon device (DEV) layer 330, 430. These SOI wafers 300, 400 are commercially available from multiple vendors and can be made with custom thickness. A tighter bend radius is achievable with a choice of a thinner device layer. The silicon device layer 330, 430 is preferably 1-20 microns and more preferably under 4 microns.

At block 220, any wiring and circuitry 304 is fabricated on the device layer 330, 430 side of the wafer. Because the device layer is semiconductor grade monocrystalline Silicon, nearly all conventional device fabrication procedures may be used at this point. This allows the addition of arbitrary structures, including high density wiring with dimensions limited only by lithography methods.

At block 230, the device layer and buried oxide layers are patterned with etching.

At block 240, a backside silicon deep reactive ion etch (or other deep silicon etching method) is used to remove the handle layer from some portions of the wafer. The buried oxide layer serves as an etch stop for this etch. The buried oxide layer may be left or removed in a subsequent step (shown left in FIG. 3 and removed in FIG. 4). The portions where the handle is removed then consist of only the device layer plus the added circuitry and are flexible since the device layer is thin silicon. The use of semiconductor processing approaches allows for arbitrarily shaped devices and multiple devices to be produced in parallel on wafer.

Exemplary embodiments address two common problems in cryogenic apparatuses such as those used for quantum computing and quantum sensors.

The first problem is that of carrying many electrical signals between different temperature stages in a cryogenic apparatus. Because of the very thin device layer, and the small dimensions of the added circuit elements, the thermal conductivity is quite low. Therefore, many wires can be carried across temperature stages with a low heat load.

The second problem is the efficient use of focal plane or detection plane area. Many instruments bring light to a small area, the focal/detection plane, and fill that area with light detectors fabricated on silicon substrates. The light detectors often require supporting circuitry to operate, but the supporting circuitry should not be in the focal plane area. By bending portion 103, the two silicon pieces (101, 102) can be placed at an angle with respect to each other, for example, at 90-degree angles to each other, allowing supporting circuitry on 103 to be out of the focal plane but still near light sensors on 101 which are in the focal plane.

Silicon is a brittle material, and therefore devices with thin flexible silicon sections in accordance with the invention are susceptible to dramatic breaking. Therefore, disclosed herein are exemplary methods to handle and protect exemplary devices such that they can be used with low risk of damage in many applications. At the same time, the monocrystalline silicon handle layer may be essentially bent unlimited times since silicon does not work harden or plastically deform.

Referring now to FIGS. 5-10, jigging 500 is shown to handle and protect exemplary flexible devices 540. The jigging 500 ensures that the forces applied to the flexible device 540 with the flexible silicon portion are controlled, repeatable, and independent of operator skill.

In FIG. 5, an exemplary flexible device 540 with a flexible portion 541 is mounted on a sample box 580 with alignment features 582 which ensure precise positioning. The alignment features 582 can be any appropriate shape configured to complimentarily accept and cradle the flexible device 540 and are therefore shaped based on the shape of the particular flexible device 540 that the jigging 500 is meant to be used with.

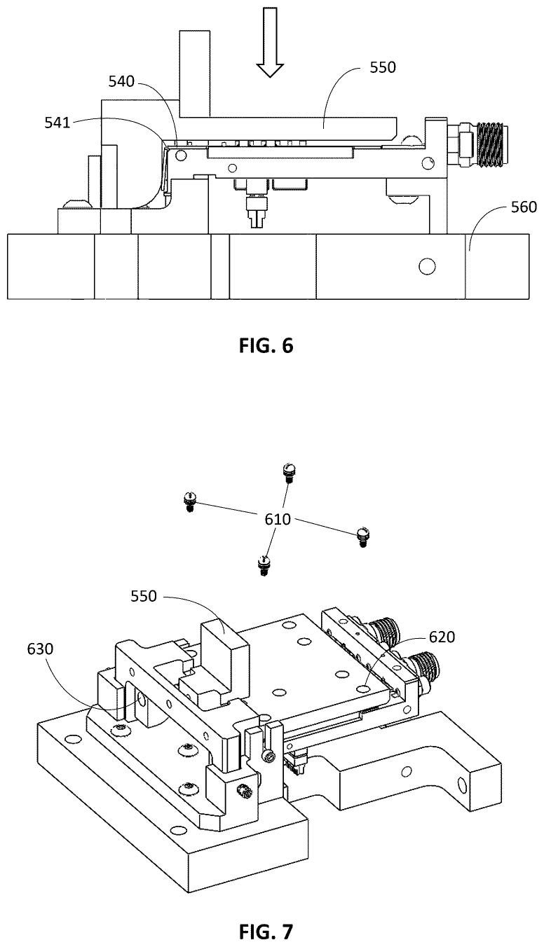

The sample box 580 is further mounted on a base 560 and guide 570. In FIG. 6, a bender 550 is guided by the guide 570. The guide may be any mechanical control means meant to guide the bender appropriately such as, for example, the slots 571 shown configured to accept rails 551 of the bender, but could also take the form of rollers, linkages, pistons, or any other appropriate mechanical control means. The resulting motion smoothly bends the device 540.

FIG. 6. shows a side view with the bender 550 fully inserted. The flexible portion 541 is bent to nearly 90 degrees. During the motion the fragile flexible portion 541 was protected by the jigging and not touched by any portions of the jigging.

Next, as shown in FIG. 7, the bender 550 may remain in place while mechanical fasteners (e.g., custom spring-loaded screws with washers) 610 are inserted through holes 620 and 630 in the bender. During screw insertion the thin fragile portion 541 may be protected from accidental contact with screw, tools, or other objects that may damage it, preferably by a mechanical cover separate from or part of the bender 550. Although any appropriate fastener may be used at 610, preferred embodiments may use custom spring-loaded screws with washers soldered to both ends of the spring may be used and are especially advantageous when used for fastening parts which will undergo differential thermal contraction or expansion.

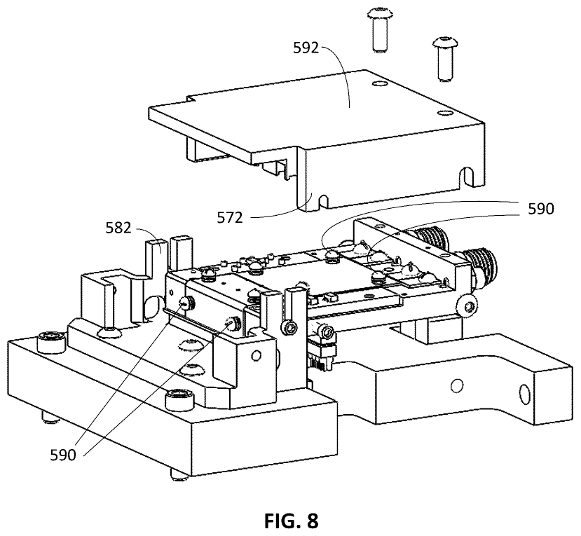

As shown in FIG. 8, the bender 550 is removed, and may be replaced by a permanent cover 592, the motion of this cover 592 may be constrained by features 572, 582, or other features, such that it cannot damage the flexible portion even if mishandled. The spring-loaded screws 590 attaching 540 to 560 are visible.

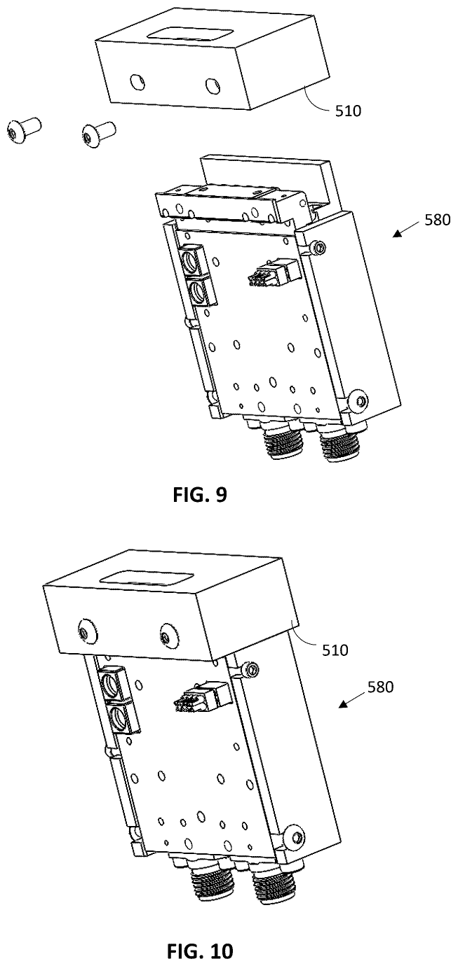

Next, as shown in FIGS. 9 and 10, the sample box 580 may be removed from the base and a final cover 510 installed.

During this whole process, the thin fragile portion may only experience forces controlled by the bender moving along the guide, or due to spring screw attachment through holes in covers. This jigging, therefore, allows reliable handling of the exemplary fragile devices.

The primary alternative technology for high density flexible wiring uses polyimide as the flexible portion. Exemplary devices are easier to fabricate than those using polyimide and are significantly easier to integrate with existing fabrication processes. Importantly, it is much easier to achieve high quality superconducting films with exemplary methods than on a polyimide substrate. The growth of superconducting films depends heavily on the underlying substrate. Here silicon is a proven substrate, and the fabrication can proceed as for devices with no flexible components as the flexibility is achieved with a subtractive process at the end.

In the space of quantum computing with superconductors, there are many start-up and large companies building computers that use 1000's of coaxial cables to bring microwave signals down to devices at ultralow temperatures (<10 mK). Exemplary devices and methods may allow these companies to scale to 100,000s of thousands of micro-wave signals or more thanks to the high density and low thermal conductivity. Unlike other efforts to develop flexible superconducting wiring, primarily based on polyimide substrates, exemplary devices are much easier to fabricate.

The processes described herein may be embodied in, and fully automated via, software code modules executed by a computing system that includes one or more general purpose computers or processors. The code modules may be stored in any type of non-transitory computer-readable medium or other computer storage device. Some or all the methods may alternatively be embodied in specialized computer hardware. In addition, the components referred to herein may be implemented in hardware, software, firmware, or a combination thereof.

Many other variations than those described herein will be apparent from this disclosure. For example, depending on the embodiment, certain acts, events, or functions described herein can be performed in a different sequence, can be added, merged, or left out altogether (e.g., not all described acts or events are necessary for the practice of the algorithms). In addition, different tasks or processes can be performed by different machines and/or computing systems that can function together.

The various illustrative logical blocks and modules described or used in connection with the embodiments disclosed herein can be implemented or performed by a machine controlled by a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In another embodiment, a processor includes an FPGA or other programmable device that performs logic operations without processing computer-executable instructions. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix(s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. A method of fabricating a flexible circuitry device using semiconductor processing, the method comprising the steps of:
fabricating wiring and/or circuitry on a device layer of a silicon-on-insulator wafer having a thick, relative to other layers of the flexible circuitry device, silicon handle layer, a buried oxide layer, and the device layer;
etching a pattern in the device and buried oxide layers; and
removing a portion of the handle layer from the wafer using a backside deep silicone etch, thereby leaving an area having only the device layer plus the added wiring and/or circuitry and is thereby flexible at that relatively thin silicon layer.

2. The method of claim 1, wherein the silicon device layer is 1-20 microns thick.

3. The method of claim 1, wherein the silicon device layer is under 4 microns thick.

4. The method of claim 1, wherein the device layer is a semiconductor grade monocrystalline Silicon layer.

5. The method of claim 1, wherein the backside deep silicone etch is a backside silicon deep reactive ion etch.

6. The method of claim 1, further comprising the step of:
removing the buried oxide layer.

7. A flexible circuitry device manufactured by semiconductor processing comprising:
a first rigid semiconductor portion having a silicon device layer and a handle layer, the handle layer of the first portion being thick relative to the device layer of the first portion;
a second rigid semiconductor portion having a silicon device layer and a handle layer, the handle layer of the second portion being thick relative to the device layer of the second portion; and
a flexible portion connecting the first rigid portion and the second rigid portion, the flexible portion having wiring electrically connecting a portion of the first rigid portion to the second rigid portion.

8. The flexible circuitry device of claim 7, wherein the wiring is resistive wiring.

9. The flexible circuitry device of claim 7, wherein the wiring is superconducting wiring.

10. The flexible circuitry device of claim 7, wherein the first rigid portion includes circuit elements fabricated on the device layer of the first rigid portion.

11. The flexible circuitry device of claim 7, wherein the flexible portion is monolithic with the device layers of the first and second rigid portions.

12. A method of using a flexible circuitry device having a flexible portion, the method comprising the steps of:
mounting the flexible circuitry device on a sample box of a jigging assembly using alignment features of the sample box tending to accept and cradle the flexible circuitry device when being mounted on the sample box;
bending the flexible circuitry device at the flexible portion using a bender of the jigging assembly, the bender guided by a guide of the jigging assembly; and
removing the flexible circuitry device from the jigging.

13. The method of claim 12, wherein the guide includes slots configured to accept rails of the bender.

14. The method of claim 12, wherein the flexible circuitry device is bent approximately 90 degrees.

15. The method of claim 12, wherein during bending, the flexible portion is protected by the jigging assembly and not touched by any portions of the jigging assembly.

16. The method of claim 15, further comprising the step of:
the bender remaining in place while mechanical fasteners are inserted through holes in the bender.

17. The method of claim 16 wherein, during insertion of the mechanical fasteners the flexible portion is protected from accidental contact by a mechanical cover.

18. The method of claim 12, further comprising the step of:
the bender remaining in place while mechanical fasteners are inserted through holes in the bender.

19. The method of claim 12, further comprising the steps of:
removing the bender from the flexible circuitry device; and
affixing a cover to the flexible circuitry device covering the flexible portion.

20. The method of claim 12, further comprising the step of:
installing a final cover on the flexible circuitry device after removal from the jigging.
